(19) United States
(12) Patent Application Publication
(10) Pub. No.: US 2025/0331365 A1
(43) Pub. Date: Oct. 23, 2025

(54) STRETCHABLE DISPLAY PANEL AND STRETCHABLE DISPLAY DEVICE

(71) Applicants: Mianyang HKC Optoelectronics Technology Co.,Ltd., MIANYANG (CN); HKC CORPORATION LIMITED, SHENZHEN (CN)

(72) Inventors: Chuan WU, SHENZHEN (CN); Zhonglin CAO, SHENZHEN (CN); Lidan YE, SHENZHEN (CN)

(73) Assignees: Mianyang HKC Optoelectronics Technology Co.,Ltd., MIANYANG (CN); HKC CORPORATION LIMITED, SHENZHEN (CN)

(21) Appl. No.: 19/001,609

(22) Filed: Dec. 26, 2024

(30) Foreign Application Priority Data
Apr. 17, 2024 (CN) 202410465276.0

(51) Int. Cl. H10K 59/122; H10K 102/00

(52) U.S. Cl. CPC H10K 59/122; H10K 2102/311

(57) ABSTRACT

A stretchable display panel and a stretchable display device. The stretchable display panel includes a first pixel layer and a second pixel layer that are arranged in a laminated manner in a stacking direction, and a pixel interlayer arranged between the first pixel layer and the second pixel layer. The pixel interlayer includes a stretchable guideline connecting the first pixel layer and the second pixel layer. In a stretched state, a light-emitting region of the first pixel layer and a light-emitting region of the second pixel layer are at least partially not overlapped in the stacking direction, under a traction of the stretchable guideline.

### CROSS REFERENCE

The present disclosure claims priority of Chinese Patent Application No. 202410465276.0, filed on Apr. 17, 2024, the entire contents of which are hereby incorporated by reference in their entirety.

### TECHNICAL FIELD

The present disclosure relates to the field of display technologies, and more specifically to a stretchable display panel and a stretchable display device.

### BACKGROUND

Compared with the liquid crystal display (LCD), the organic light emitting diode (OLED) display panel has many advantages, such as all-solid state, active light emitting, high brightness, high contrast, ultra-thin, low power consumption, no viewing angle limitation, wide operating temperature range, etc., and is thus receiving more and more attention.

A stretchable flexible OLED display technology is an innovative technology that combines inorganic electronic display devices with a flexible structured substrate material, making the display screen capable of arbitrary deformation. By virtue of the flexible nature of organic optoelectronic materials, the flexible OLED display products that can be bent and folded have already penetrated the consumer market. With the development of stretchable electronics, stretchable OLEDs with greater freedom of deformation have become a hot topic of interest in scientific research and industry. Compared with flat OLEDs, the stretchable OLEDs have the following advantages: (1) they can be deformed arbitrarily, making it possible to prepare more portable display devices, which greatly improves space utilization; 2) true “three-dimensional” display: relying on morphological changes, they can truly achieve three-dimensional dynamic simulation and three-dimensional dynamic display; 3) they can be attached to any surface and can be placed on various flat and curved surfaces in a conformal manner, realizing people's vision of “any surface is a screen”.

However, for a conventional stretchable display product after being stretched, the stretchable display product is often accompanied by adverse phenomena such as reduced display brightness, poor luminous uniformity, and cracks in the film, etc. In most stretchable display products, the stretchable elastomer is deformed, and the light-emitting region remains unchanged. Based on this, the pixel density (PPI) of the display product after being stretched will decrease with the increase of stretching stress, and the display brightness will also decrease significantly. Since consumers are updating their display products more and more quickly, this type of design obviously cannot meet the market demand. Therefore, maintaining the stability of the photoelectric performance and display quality before and after stretching is a hot topic for industry personnel.

### SUMMARY OF THE DISCLOSURE

The main technical problem solved in the present disclosure is to provide a stretchable display panel and a stretchable display device, which solves the problems of reduced brightness and deterioration of light-emitting uniformity of the existing stretchable OLED display.

To solve the above technical problem, the present disclosure provides a stretchable display panel, including: a first pixel layer and a second pixel layer that are arranged in a laminated manner in a stacking direction, and a pixel interlayer arranged between the first pixel layer and the second pixel layer; wherein the pixel interlayer includes a stretchable guideline connecting the first pixel layer and the second pixel layer; wherein in a stretched state, a light-emitting region of the first pixel layer and a light-emitting region of the second pixel layer are at least partially not overlapped in the stacking direction, under a traction of the stretchable guideline.

In some embodiments, the stretchable guideline is in an extreme stretched state in both the stretched state and a non-stretched state of the stretchable display panel.

In some embodiments, a stretching state of the stretchable guideline is opposite to a stretching state of the stretchable display panel; in condition of the stretchable display panel being in the stretched state, the stretchable guideline is in a contracted state; in condition of the stretchable display panel being in a non-stretched state, the stretchable guideline is in an extreme stretched state.

In some embodiments, the first pixel layer includes a plurality of first light-emitting units and a plurality of first stretchable portions arranged around the plurality of first light-emitting units, and each first stretchable portion between corresponding adjacent two first light-emitting units defines a first stress relief hole; the second pixel layer includes a plurality of second light-emitting units and a plurality of second stretchable portions arranged around the plurality of second light-emitting units, and each second stretchable portion between corresponding adjacent two second light-emitting units defines a second stress relief hole; in condition of the stretchable display panel being in the stretched state, a corresponding second light-emitting unit and the first stress relief hole are at least partially overlapped.

In some embodiments, at least the first stress relief hole is filled with a stretchable polymer material, and the stretchable polymer material is in a light-transmitting state in condition of the stretchable display panel being in the stretched state.

In some embodiments, the second stress relief hole is filled with the stretchable polymer material.

In some embodiments, the stretchable polymer material has a negative Poisson's ratio; a projection of each of the first stress relief hole and the second stress relief hole on the stretchable display panel is of a square or circular shape.

In some embodiments, the stretchable display panel further includes a third pixel layer; the third pixel layer includes a plurality of third light-emitting units and a plurality of third stretchable portions arranged around the plurality of third light-emitting units, and each third stretchable portion between corresponding adjacent two third light-emitting units defines a third stress relief hole.

In some embodiments, in condition of the stretchable display panel being in the stretched state, a corresponding third light-emitting unit is at least partially overlapped with the first stress relief hole and the second stress relief hole.

To solve the above technical problem, the present disclosure further provides a stretchable display device, including the stretchable display panel as above.

The beneficial effect of the present disclosure is as followed: The first pixel layer and the second pixel layer are connected by a stretchable guideline in the pixel interlayer, and the stretchable guideline has a guiding effect when stretched, such that the first pixel layer and the second pixel layer are pulled in opposite directions by the stretchable guideline. In this way, the light-emitting regions of the first pixel layer and the second pixel layer are not overlapped at least partially in the stacking direction, and the light-emitting region of the first pixel layer or the second pixel layer is overlapped with the non-light-emitting region of first pixel layer. Further, the light-emitting region of the second pixel layer can emit light to the light-emitting surface by setting a light-transmitting material in the non-light-emitting region of the first pixel layer, thereby solving the problems of reduced brightness and poor light uniformity of existing stretchable OLED displays, and maintaining the stability of the photoelectric performance and display quality before and after stretching.

### BRIEF DESCRIPTION OF THE DRAWINGS

In order to more clearly illustrate the technical solutions in the embodiments of the present disclosure, the accompanying drawings to be used in the description of the embodiments will be briefly introduced below, and it will be obvious that the accompanying drawings in the following description are only some of the embodiments of the present disclosure, and other accompanying drawings can be obtained according to these drawings for the those skilled in the art, without any creative labor.

FIG. 1 is a schematic structural view of a stretchable display panel according to some embodiments of the present disclosure.

FIG. 2 is a schematic structural view of a stretchable display panel, after being stretched, according to some embodiments of the present disclosure.

FIG. 3 is a top structural schematic view of a stretchable display panel, after being stretched, according to some embodiments of the present disclosure.

FIG. 4 is a schematic structural view of a stretchable display panel according to a first implementation of the present disclosure.

FIG. 5 is schematic structural view of a stretchable display panel according to a second implementation of the present disclosure.

FIG. 6 is a schematic structural view of a display panel according to some embodiments of the present disclosure.

FIG. 7 is schematic structural view of a stretchable display panel according to a third implementation of the present disclosure.

FIG. 8 is a schematic structural view of a stretchable display device according to some embodiments of the present disclosure.

Reference numerals: 100 first pixel layer; 200 second pixel layer; 110 pixel interlayer; 111 stretchable guideline; 101 first light-emitting unit; 102 first stretchable portion; 103 first stress relief hole; 201 second light-emitting unit; 202 second stretchable portion; 203 second stress relief hole; 300 third pixel layer; 301 third light-emitting unit; 302 third stretchable portion; 303 third stress relief hole.

### DETAILED DESCRIPTION

The technical solutions in the embodiments of the present disclosure will be clearly and completely described below in conjunction with the accompanying drawings in the embodiments of the present disclosure, and it is clear that the embodiments described are only a part of the embodiments of the present disclosure and not all of the embodiments. Based on the embodiments in the present disclosure, all other embodiments obtained by those skilled in the art without making creative labor are within the scope of the present disclosure.

The terms used in the embodiments of the present disclosure are intended solely for the purpose of describing particular embodiments and are not intended to limit the present disclosure. The singular forms of “a”, “said”, and “the” used in the embodiments and the appended claims of the present disclosure are intended to encompass the plural form, unless other meanings are clearly indicated above. The terms of “plurality” generally encompasses at least two, but does not preclude the inclusion of at least one.

It should be understood that the term “and/or” used in this document is only a descriptive association of related objects, indicating that there can be three relationships, for example, A and/or B, which can indicate three situations: A alone, A and B at the same time, and B alone. In addition, the character “/” in this document generally indicates that the objects associated before and after are in an “or” relationship. The terms “first,” “second,” etc. in the description, claims, and drawings of the present disclosure are intended to distinguish similar objects, and do not necessarily indicate a specific order or sequence.

It should be understood that the terms “comprising”, “including”, or any other variations thereof, as used herein, are intended to encompass non-exclusive inclusion, such that a process, method, article, or apparatus that includes a set of elements includes not only those elements but also other elements that are not explicitly listed or that are inherent to such process, method, article, or apparatus, or further includes elements that are inherent to such process, method, article, or apparatus. Without further limitation, the fact that an element is defined by the phrase “including . . . ” does not exclude the existence of another identical element in the process, method, article, or apparatus including the element.

It should be noted that when the embodiments of the present disclosure involve directional indications (e.g., up, down, left, right, forward, backward . . . ), the directional indications are only intended to explain a relative positional relationship, movement, etc., between components in a particular attitude (as shown in the accompanying drawings), and if the particular attitude changes, the directional indications change accordingly.

Reference to “embodiments” herein means that particular features, structures, or characteristics described in conjunction with the embodiments may be included in at least one embodiment of the present disclosure. The presence of the phrase at various points in the specification does not necessarily refer to the same embodiments or to separate or alternative embodiments that are mutually exclusive of other embodiments. It is understood by those skilled in the art, both explicitly and implicitly, that the embodiments described herein may be combined with other embodiments.

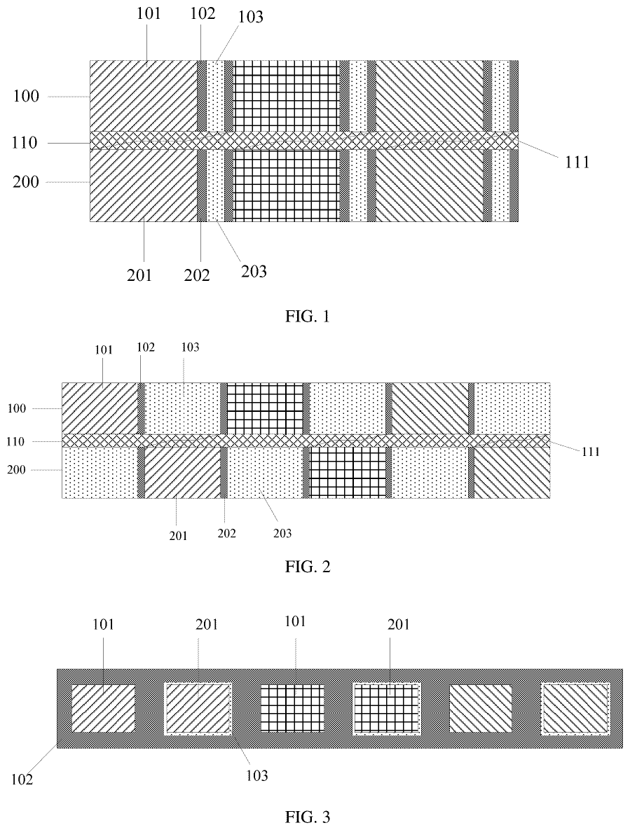

The present disclosure provides a stretchable display panel. Specifically, referring to FIG. 1, FIG. 1 is a schematic structural view of a stretchable display panel according to some embodiments of the present disclosure. The stretchable display panel includes a first pixel layer 100 and a second pixel layer 200 arranged in a laminated manner, and a pixel interlayer 110 arranged between the first pixel layer 100 and the second pixel layer 200. The pixel interlayer 110 includes a stretchable guideline 111 connecting the first pixel layer 100 and the second pixel layer 200.

In the embodiments, the first pixel layer 100 and the second pixel layer 200 can move in opposite directions under the traction of the stretchable guideline 111, such that a light-emitting region of the first pixel layer 100 and a light-emitting region of the second pixel layer 200 are not overlapped at least partially in the stacking direction. In other words, the first pixel layer 100 and the second pixel layer 200 can move in a misalignment direction under the traction of the stretchable guideline 111. For example, the first pixel layer 100 moves to the left (or away from a light-emitting layer of the second pixel layer 200) under the traction of the stretchable guideline 111, and the second pixel layer 200 moves to the right (or away from a light-emitting layer of the first pixel layer 100) under the traction of the stretchable guideline 111. Specifically, the light-emitting region of the first pixel layer 100 and a non-light-emitting region of the second pixel layer 200 are overlapped in the stacking direction, and the light-emitting region of the second pixel layer 200 and a non-light-emitting region of the first pixel layer 100 are overlapped in the stacking direction. It should be noted that the stacking direction is perpendicular to a projection direction of the stretchable display panel.

In particular, referring to FIG. 2, FIG. 2 is a schematic structural view of a stretchable display panel, after being stretched, according to some embodiments of the present disclosure. Each of the first pixel layer 100 and the second pixel layer 200 includes a light-emitting unit and a stretchable portion, where the light-emitting unit faces the light-emitting region of the corresponding pixel layer, and the stretchable portion faces the non-light-emitting region of the corresponding pixel layer. As shown in FIG. 2, the first pixel layer 100 includes multiple first light-emitting units 101 and multiple first stretchable portions 102 arranged around the multiple first light-emitting units 101, and each first stretchable portion 102 between corresponding adjacent two first light-emitting units 101 defines a first stress relief hole 103. The second pixel layer 200 includes multiple second light-emitting units 201 and multiple second stretchable portions 202 arranged around the multiple second light-emitting units 201, and each second stretchable portion 202 between corresponding adjacent two second light-emitting units 201 defines a second stress relief hole 203. In a stretched state, the second light-emitting unit 201 and the first stress relief hole 103 are at least partially overlapped (in the projection direction), and the first light-emitting unit 101 and the second stress relief hole 203 are at least partially overlapped.

In the embodiments, the light-emitting directions of the first pixel layer 100 and the second pixel layer 200 are the same; the first pixel layer 100 is on a light-emitting side of the second pixel layer 200. In other embodiments, the second pixel layer 200 is on a light-emitting side of the first pixel layer 100. The present disclosure does not limit in this regard.

The present disclosure further provides a schematic view of the top view structure of a stretchable display panel. Specifically, referring to FIG. 3, FIG. 3 is a top structural schematic view of a stretchable display panel, after being stretched, according to some embodiments of the present disclosure. When the stretchable display panel is stretched to 200%, that is, the stretchable portion reaches 100% (equivalent to one light-emitting unit). The second light-emitting unit 201 and the first stress relief hole 103 can be completely overlapped in the stacking direction, such that the second light-emitting unit 201 can emit light through the first stress relief hole 103 by 100%. Therefore, in a double-layer stretchable display panel, it is optimal when the stretchable display panel is stretched to 200%. In a specific embodiment, the stretchable display panel is preferably stretched to 150% to 300%.

In the embodiments, at least the first stress relief hole 103 is filled with a stretchable polymer material, where the stretchable polymer material is in a light-transmitting state in a stretched state. The light-transmitting state includes full transparency and semi-transparency, which are not limited herein. Obviously, the display effect of full transparency is better. In particular, the stretchable polymer material includes polyimide, etc., without limitation herein. In a further embodiment, the second stress relief hole 103 is also filled with the stretchable polymer material that can be light-transparent. In other embodiments, since the second stress relief hole 103 is arranged on a backlight side of the first pixel layer 100, the second stress relief hole 103 may be arranged as an opaque part, without limitation herein.

In particular, the stretchable polymer material has a negative Poisson's ratio. The negative Poisson's ratio means that when the material is stretched, it expands laterally within the elastic range; while when it is compressed, it contracts laterally.

In the embodiments, the first stress relief hole 103 and the second stress relief hole 203 are each a square or circular hole when viewed in the projection direction of the stretchable display panel (i.e., in the stacking direction, which is also a top view). In particular, it can be understood that when the stress relief holes (including the first stress relief hole 103, the second stress relief hole 203, and also including a third stress relief hole, etc.) are square or circular holes, the stretchable polymer material can be stretched in a stretching plane, including transverse stretching and longitudinal stretching, thereby enlarging the stress relief holes, thereby enabling the light emitted by the light-emitting region of the second pixel layer to pass through. In other specific embodiments, the shapes of the first stress relief hole 103 and the second stress relief hole 203 in the top view may be set to be the same as the shapes of the light-emitting units (including the first light-emitting unit, the second light-emitting unit, etc.) in the top view, without limitation herein.

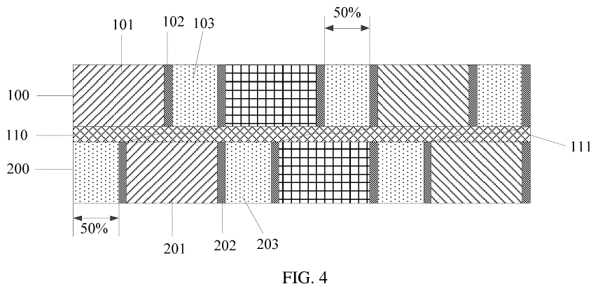

In a specific embodiment, the stretchable guideline 111 is in an extreme stretched state in both the stretched and non-stretched states. Referring to FIGS. 1 and 2, in the embodiments, the amount of misalignment between the second pixel layer 200 and the first pixel layer 100 is proportional to the amount of stretching of the stretchable display panel. When the stretchable display panel is stretched to 150%, that is, when the stretchable portion is stretched to 50% of one light-emitting unit, the amount of misalignment between the first pixel layer 100 and the second pixel layer 200 is 50%. Referring to FIG. 4, FIG. 4 is a schematic structural view of a stretchable display panel according to a first implementation of the present disclosure. A first one of the multiple second light-emitting units 201 of the second pixel layer 200 is connected to a second one of the multiple first light-emitting units 101 of the first pixel layer 100 through the stretchable guideline 111, that is, the second light-emitting unit 201 and the first light-emitting unit 101 are connected at a misalignment, such that a misalignment between the first light-emitting unit 101 and the second light-emitting unit 201 is realized after the first stretchable portion 102 of the first pixel layer 100 is stretched. It should be noted that when the stretchable portion is not stretched, the first one of the multiple second light-emitting units 201 of the second pixel layer 200 and a first one of the multiple first light-emitting units 101 of the first pixel layer 100 are arranged in a face-to-face (overlapping) manner, i.e. on the same projection surface. After the stretchable portion is stretched, the first pixel layer 100 and the second pixel layer 200 are misaligned in the stacking direction. In some embodiments, the light-emitting unit 201 of the second pixel layer 200 is laminated with the first stress relief hole 103 of the first pixel layer 100. In the embodiments, the stretchable guideline 111 has a constant length during the stretching process. In some embodiments, the stretchable guideline 111 can be connected to the first light-emitting unit 101 and the second light-emitting unit 201 that are adjacent and misaligned from each other, or it can be connected to the first stress relief hole 103 of the first pixel layer 100 and the second light-emitting unit 201 of the second pixel layer 200, or it can be connected to the first light-emitting unit 101 of the first pixel layer 100 and the second stress relief hole 203 of the second pixel layer 200, etc., without limitation herein.

In other words, each second light-emitting unit 201 of the second pixel layer 200 is connected to a first light-emitting unit 101 that is adjacent to a first light-emitting unit 101 facing the second light-emitting unit 201. Each first light-emitting unit 101 is connected to a second light-emitting unit 201 that is adjacent to a second light-emitting unit 201 right under the positive projection of the first light-emitting unit 101. Each second light-emitting unit 201 is connected to a first light-emitting unit 101 that is adjacent to a first light-emitting unit 101 right above the positive projection of the second light-emitting unit 201.

In the embodiments, the second light-emitting unit 201 of the second pixel layer 200 moves away from the first light-emitting unit 101 right above the positive projection of the second light-emitting unit 201 (that is, towards the stress relief hole between the two first light-emitting units 101) under the stretching and expansion of the first stretchable portion 102, such that the second light-emitting unit 201 and the first light-emitting unit 101 are not overlapped at least partially in the stretched state. Further, light passes through the stress relief hole for display, filling the pixel density of the first pixel layer 100 after being stretched, thereby solving the problems of reduced display brightness and poor light uniformity due to reduced pixel density, so as to maintain the stability of the photoelectric performance and display quality before and after stretching. In particular, the stretchable guideline 111 may be connected to a center or edge of one first light-emitting unit 101 and a center or edge of one second light-emitting unit 201, without limitation herein.

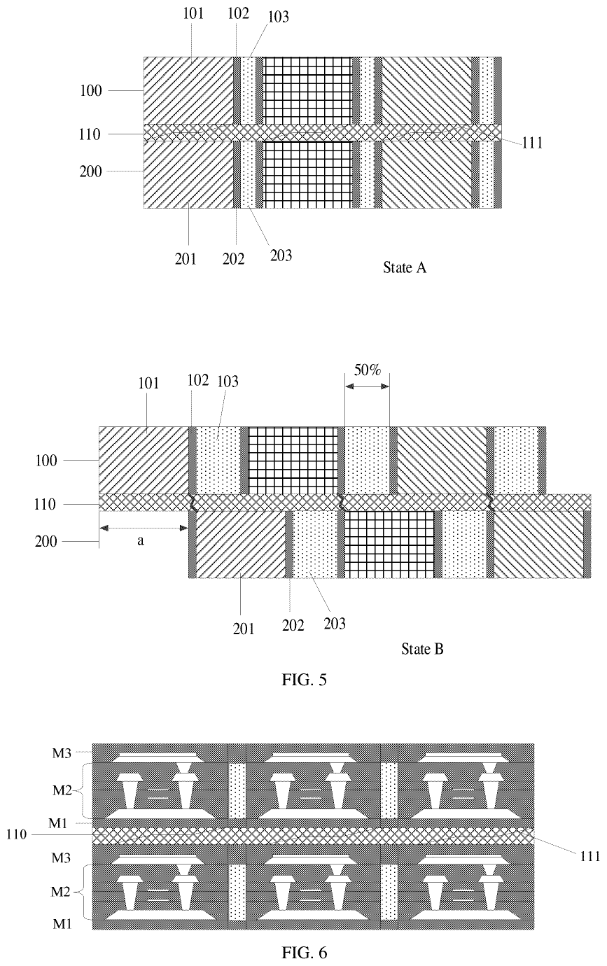

In another specific embodiment, the stretching state of the stretchable guideline 111 is opposite to the stretching state of the stretchable display panel. Specifically, when the stretchable display panel is in a stretched state, the stretchable guideline 111 is in a contracted state, and when the stretchable display panel is in a non-stretched state, the stretchable guideline 111 is in an extreme stretched state. For further details, referring to FIG. 5, FIG. 5 is schematic structural view of a stretchable display panel according to a second implementation of the present disclosure. The stretchable guideline 111 in the non-stretched state is shown as A in FIG. 5 and in the stretched state as B in FIG. 5. As shown in FIG. 5, when the stretchable display panel is stretched to 150%, that is, the stretchable portion is stretched to 50% of one light-emitting unit, the mount of misalignment of the first light-emitting unit 101 and the second light-emitting unit 201 does not change with the amount of stretching, but is proportional to the amount of contraction of the stretchable guideline 111. As shown in B in FIG. 5, when the stretchable guideline 111 is contracted, it causes the second light-emitting unit 201 to move away from the first light-emitting unit 101, thereby causing the first light-emitting unit 101 and the second light-emitting unit 201 to be misaligned.

In some embodiments, the stretchable guideline 111 is connected to a rightmost edge of one first light-emitting unit 101 and a leftmost edge of one second light-emitting unit 201. That is, the side edge of the first light-emitting unit 101 is connected to the other side edge of the second light-emitting unit 201 via the stretchable guideline 111. It is not limited to the case where the side edge is on the left and the other side edge is on the right, or where the side edge is on the right and the other side edge is on the left. In other words, the side edge of each first light-emitting unit 101 is connected to the other side edge of the second light-emitting unit 201 that is right under the positive projection of the first light-emitting unit 101. This is, the first light-emitting unit 101 is connected to the second light-emitting unit 201 that is right under the positive projection of the first light-emitting unit 101, and the edge of the first light-emitting unit 101 on one side is connected to the other side of the second light-emitting unit 201 that is furthest away from the first light-emitting unit 101.

In the embodiments, the amount of misalignment between the first light-emitting unit 101 and the second light-emitting unit 201 is controlled by the amount of extension and contraction of the stretchable guideline 111, and is a constant value a. In the embodiments, no matter how much the first pixel layer 100 and the second pixel layer 200 are stretched, after stretching, the amount of misalignment between the first light-emitting unit 101 and the second light-emitting unit 201 is always a.

Compared to the first implementation, the second implementation has the disadvantage that the stretchable guideline 111 cannot return to its non-stretched state after being stretched, i.e. the stretchable guideline 111 after being stretched relies on an external force (cannot recover on its own) to return to its extreme stretched state. Whereas the advantage of the second implementation is that the stretchable guideline 111 has a contraction property and is not easily broken. Moreover, the misalignment amount of the first light-emitting unit 101 and the second light-emitting unit 201 is a certain value, which can ensure that the first light-emitting unit 101 and the second light-emitting unit 201 are always misaligned, and the misalignment amount is related to the extension and contraction amount of the stretchable guideline 111 (the difference between extension and contraction), which can be maintained at a certain value.

Furthermore, in the above embodiments, the first pixel layer 100 and the second pixel layer 200 are both single-layer stretchable display panels or single-layer array display substrates. Further, referring to FIG. 6, FIG. 6 is a schematic structural view of a display panel according to some embodiments of the present disclosure. Each of the first pixel layer 100 and the second pixel layer 200 includes a substrate layer M1, an array driving layer M2, and a pixel layer M3. The array driving layer M2 includes multiple metal lines and a transistor TFT formed by the metal lines, without limitation herein. The stress relief holes are arranged in the array driving layer M2 and may extend to the substrate layer M1 and the pixel layer M3, without limitation herein. The substrate layer M1 is generally a glass substrate that can transmit light, and the pixel layer M3 has the light-emitting layer formed therein that can also transmit light.

In some embodiments, the first pixel layer 100 and the second pixel layer 200 are both single-layer stretchable display panels, and the stretchable display panel in the present disclosure is a double-layer display panel.

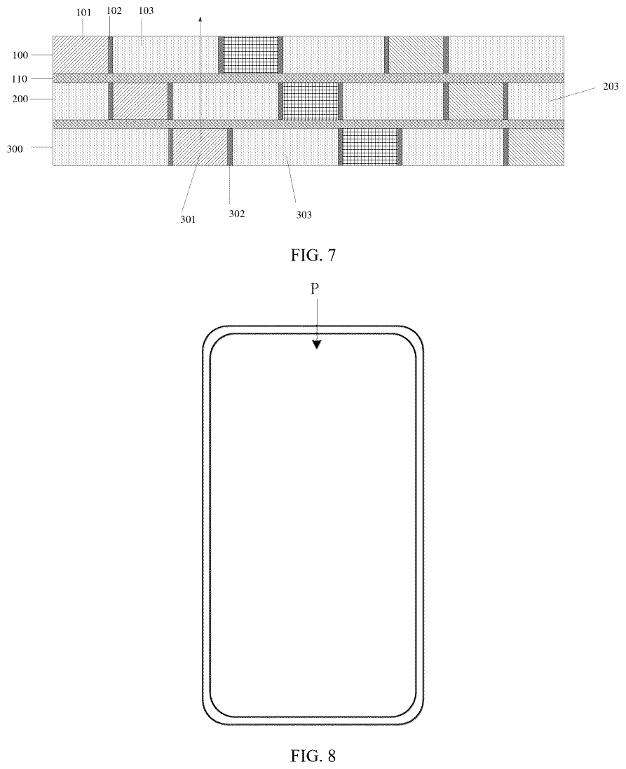

Further, the stretchable display panel may be a three-layer stretchable display panel. In particular, referring to FIG. 7, FIG. 7 is schematic structural view of a stretchable display panel according to a third implementation of the present disclosure. The stretchable display panel includes, in addition to the first pixel layer 100 and the second pixel layer 200, a third pixel layer 300. The third pixel layer 300 may be arranged on a side of the second pixel layer 200 away from the first pixel layer 100, without limitation herein.

The third pixel layer 300 includes third light-emitting units 301 and third stretchable portions 302 arranged around the third light-emitting units 301, and each third stretchable portion 302 between corresponding adjacent two third light-emitting units 301 defines a third stress relief hole 303. In particular, in the stretched state, the third light-emitting unit 301 is at least partially overlapped with the first stress relief hole 103 and the second stress relief hole 203, such that the third light-emitting unit 301 emits light to the display surface through the second stress relief hole 203 and the first stress relief hole 103 for display.

When conditions permit, the stretchable display panel may further include four layers of stretchable display panels, five layers of stretchable display panels, etc., without limitation. It is understood that the stretching of the display panel includes stretching in a horizontal direction and stretching in a vertical direction on the stretching plane. In addition to the stress relief holes provided between two adjacent light-emitting units in the same row (see FIG. 3), stress relief holes may further be provided between two light-emitting units in adjacent rows, without limitation herein.

In the embodiments, in the non-stretch state, the first light-emitting unit 101 and the second light-emitting unit 201 that is overlapped with it emit the same color, that is, they are sub-pixels of the same color. In this way, after stretching, the luminous area of the sub-pixels of the same color is enlarged. In the embodiments, after stretching, the luminous area of each sub-pixel of the same color is enlarged, thereby avoiding the problem of color deviation caused by the stretching mount of the stretchable portion not reaching 100%. This problem can be further explained as that, when the luminous area of the second light-emitting unit 201 is smaller than the luminous area of the first light-emitting unit 101, in a case where the second light-emitting unit 201 and the first light-emitting unit 101 emit light of different colors, color deviation in the display may occur.

It should be noted that the pixel interlayer 110 is of a transparent stretchable material, and when stretched, it can be stretched in a misaligned manner. That is, a surface on a side of the pixel interlayer 110 close to the first pixel layer 100 and a surface on a side of the pixel interlayer 110 close to the second pixel layer 200 are stretched in opposite directions, for example, one surface is stretched to the left and the other surface is stretched to the right. For details of the implementation of the pixel interlayer 110, reference may be made to materials with hollows, such as foam and sponge.

The present disclosure further provides a stretchable display device. Referring to FIG. 8, FIG. 8 is a schematic structural view of a stretchable display device according to some embodiments of the present disclosure. The stretchable display device includes a stretchable display panel as described in any of the above embodiments. In some embodiments, the stretchable display device P includes, but is not limited to, a mobile phone, a tablet computer, a digital camera, etc.

The beneficial effect of the present disclosure is as followed: The first pixel layer and the second pixel layer are connected by a stretchable guideline in the pixel interlayer, and the stretchable guideline has a guiding effect when stretched, such that the first pixel layer and the second pixel layer are pulled in opposite directions by the stretchable guideline. In this way, the light-emitting regions of the first pixel layer and the second pixel layer are not overlapped at least partially in the stacking direction, and the light-emitting region of the first pixel layer or the second pixel layer is overlapped with the non-light-emitting region of first pixel layer. Further, the light-emitting region of the second pixel layer can emit light to the light-emitting surface by setting a light-transmitting material in the non-light-emitting region of the first pixel layer, thereby solving the problems of reduced brightness and poor light uniformity of existing stretchable OLED displays, and maintaining the stability of the photoelectric performance and display quality before and after stretching.

The above is only some embodiments of the present disclosure, and is not intended to limit the scope of the present disclosure. Any equivalent structure or equivalent process transformation utilizing the contents of the specification of the present disclosure and the accompanying drawings, or directly or indirectly utilized in other related technical fields, are all reasonably included in the scope of the present disclosure.

What is claimed is:

1. A stretchable display panel, comprising: a first pixel layer and a second pixel layer that are arranged in a laminated manner in a stacking direction, and a pixel interlayer arranged between the first pixel layer and the second pixel layer; wherein the pixel interlayer comprises a stretchable guideline connecting the first pixel layer and the second pixel layer;
wherein in a stretched state, a light-emitting region of the first pixel layer and a light-emitting region of the second pixel layer are at least partially not overlapped in the stacking direction, under a traction of the stretchable guideline.

2. The stretchable display panel according to claim 1, wherein the stretchable guideline is in an extreme stretched state in both the stretched state and a non-stretched state of the stretchable display panel.

3. The stretchable display panel according to claim 1, wherein a stretching state of the stretchable guideline is opposite to a stretching state of the stretchable display panel;
in condition of the stretchable display panel being in the stretched state, the stretchable guideline is in a contracted state;
in condition of the stretchable display panel being in a non-stretched state, the stretchable guideline is in an extreme stretched state.

4. The stretchable display panel according to claim 2, wherein,
the first pixel layer comprises a plurality of first light-emitting units and a plurality of first stretchable portions arranged around the plurality of first light-emitting units, and each first stretchable portion between corresponding adjacent two first light-emitting units defines a first stress relief hole;
the second pixel layer comprises a plurality of second light-emitting units and a plurality of second stretchable portions arranged around the plurality of second light-emitting units, and each second stretchable portion between corresponding adjacent two second light-emitting units defines a second stress relief hole;
in condition of the stretchable display panel being in the stretched state, a corresponding second light-emitting unit and the first stress relief hole are at least partially overlapped.

5. The stretchable display panel according to claim 4, wherein at least the first stress relief hole is filled with a stretchable polymer material, and the stretchable polymer material is in a light-transmitting state in condition of the stretchable display panel being in the stretched state.

6. The stretchable display panel according to claim 5, wherein the second stress relief hole is filled with the stretchable polymer material.

7. The stretchable display panel according to claim 5, wherein the stretchable polymer material has a negative Poisson's ratio; a projection of each of the first stress relief hole and the second stress relief hole on the stretchable display panel is of a square or circular shape.

8. The stretchable display panel according to claim 6, wherein the stretchable display panel further comprises a third pixel layer; the third pixel layer comprises a plurality of third light-emitting units and a plurality of third stretchable portions arranged around the plurality of third light-emitting units, and each third stretchable portion between corresponding adjacent two third light-emitting units defines a third stress relief hole.

9. The stretchable display panel according to claim 8, wherein in condition of the stretchable display panel being in the stretched state, a corresponding third light-emitting unit is at least partially overlapped with the first stress relief hole and the second stress relief hole.

10. The stretchable display panel according to claim 3, wherein the stretchable guideline is connected to a rightmost edge of a corresponding first light-emitting unit and a leftmost edge of a corresponding second light-emitting unit.

11. The stretchable display panel according to claim 4, wherein in condition of the stretchable display panel being in a non-stretched state, a color of each first light-emitting unit is the same as a color of a corresponding second light-emitting unit that is overlapped with the first light-emitting unit.

12. A stretchable display device, comprising a stretchable display panel;
wherein the stretchable display panel comprises: a first pixel layer and a second pixel layer that are arranged in a laminated manner in a stacking direction, and a pixel interlayer arranged between the first pixel layer and the second pixel layer; wherein the pixel interlayer comprises a stretchable guideline connecting the first pixel layer and the second pixel layer;
wherein in a stretched state, a light-emitting region of the first pixel layer and a light-emitting region of the second pixel layer are at least partially not overlapped in the stacking direction, under a traction of the stretchable guideline.

13. The stretchable display device according to claim 12, wherein the stretchable guideline is in an extreme stretched state in both the stretched state and a non-stretched state of the stretchable display panel.

14. The stretchable display device according to claim 12, wherein a stretching state of the stretchable guideline is opposite to a stretching state of the stretchable display panel;
in condition of the stretchable display panel being in the stretched state, the stretchable guideline is in a contracted state;
in condition of the stretchable display panel being in a non-stretched state, the stretchable guideline is in an extreme stretched state.

15. The stretchable display device according to claim 13, wherein,
the first pixel layer comprises a plurality of first light-emitting units and a plurality of first stretchable portions arranged around the plurality of first light-emitting units, and each first stretchable portion between corresponding adjacent two first light-emitting units defines a first stress relief hole;
the second pixel layer comprises a plurality of second light-emitting units and a plurality of second stretchable portions arranged around the plurality of second light-emitting units, and each second stretchable portion between corresponding adjacent two second light-emitting units defines a second stress relief hole;
in condition of the stretchable display panel being in the stretched state, a corresponding second light-emitting unit and the first stress relief hole are at least partially overlapped.

16. The stretchable display device according to claim 15, wherein at least the first stress relief hole is filled with a stretchable polymer material, and the stretchable polymer material is in a light-transmitting state in condition of the stretchable display panel being in the stretched state.

17. The stretchable display device according to claim 16, wherein the second stress relief hole is filled with the stretchable polymer material.

18. The stretchable display device according to claim 16, wherein the stretchable polymer material has a negative Poisson's ratio; a projection of each of the first stress relief hole and the second stress relief hole on the stretchable display panel is of a square or circular shape.

19. The stretchable display device according to claim 17, wherein the stretchable display panel further comprises a third pixel layer; the third pixel layer comprises a plurality of third light-emitting units and a plurality of third stretchable portions arranged around the plurality of third light-emitting units, and each third stretchable portion between corresponding adjacent two third light-emitting units defines a third stress relief hole.

20. The stretchable display device according to claim 19, wherein in condition of the stretchable display panel being in the stretched state, a corresponding third light-emitting unit is at least partially overlapped with the first stress relief hole and the second stress relief hole.
